(19) United States
(12) Patent Application Publication
(10) Pub. No.: US 2010/0129984 A1
(43) Pub. Date: May 27, 2010

(54) WAFER SINGULATION IN HIGH VOLUME MANUFACTURING

(76) Inventors: George Vakanas, Tempe, AZ (US); George Chen, Los Gatos, CA (US); Yuval Greenzweig, Hasharon (IL); Eric Li, Chandler, AZ (US); Sergei Voronov, Chandler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/324,692

(22) Filed: Nov. 26, 2008

(51) Int. Cl. H01L 21/02; B23K 26/02

(52) U.S. Cl. 438/463; 219/121.67; 257/E21.002

(57) ABSTRACT

The present invention discloses an apparatus including: a laser beam directed at a wafer held by a chuck in a process chamber; a focusing mechanism for the laser beam; a steering mechanism for the laser beam; an optical scanning mechanism for the laser beam; a mechanical scanning system for the chuck; an etch chemical induced by the laser beam to etch the wafer and form volatile byproducts; a gas feed line to dispense the etch chemical towards the wafer; and a gas exhaust line to remove any excess of the etch chemical and the volatile byproducts.

### CROSS REFERENCE TO RELATED APPLICATION

This is a Continuation-in-part of serial No. (TBD), filed on Oct. 28, 2008, which is currently pending.

### BACKGROUND OF THE INVENTION

1. Field of the Invention

The present invention relates to a field of semiconductor fabrication and, more specifically, to an apparatus for and method of singulating a wafer in high volume manufacturing.

2. Discussion of Related Art

Singulating a wafer involves separation of a substrate into individual die. A backside of a wafer to be singulated is first subjected to backgrinding, followed by polishing. Then, a laser beam is used from the backside of the wafer to form a series of modified layers inside the wafer, extending from the active surface of the wafer to the backside of the wafer. Deterioration sites are formed in the modified layers along scribelines that are arranged in a lattice pattern across an active surface of the wafer. Then, the wafer is mounted onto a dicing tape and singulated by expanding the dicing tape to separate the wafer through the deterioration sites. Individual die are picked from the dicing tape.

Issues that may arise include rough edges, uneven street width, residual stress, and delamination in low-k dielectric layers on the die.

### BRIEF DESCRIPTION OF THE DRAWINGS

FIG. 1 shows an apparatus for laser scribing and laser-assisted chemical singulation of a wafer according to an embodiment of the present invention.

FIGS. 2-7 show a substrate separated into smaller portions having different sizes and shapes by laser scribing and laser-assisted chemical singulation according to various embodiments of the present invention.

FIG. 8 shows processes involved in laser scribing and laser-assisted chemical etching in an embodiment of the present invention.

FIG. 9 shows different methods of laser scribing and laser-assisted chemical etching according to various embodiments of the present invention.

### DETAILED DESCRIPTION OF THE PRESENT INVENTION

In the following description, numerous details of specific materials, features, dimensions, processes, and sequences are set forth to provide a thorough understanding of the present invention. However, in some instances, one skilled in the art will realize that the invention may be practiced without these particular details. In other instances, one skilled in the art will also realize that certain well-known details have not been described so as to avoid obscuring the present invention.

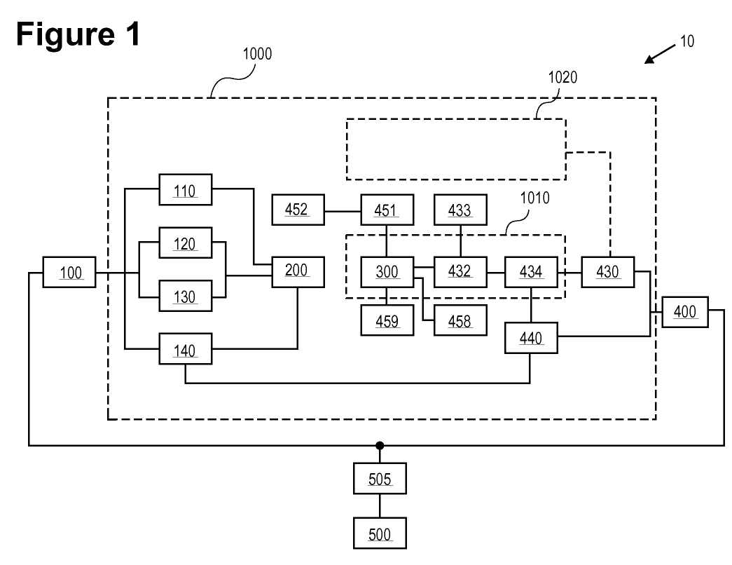

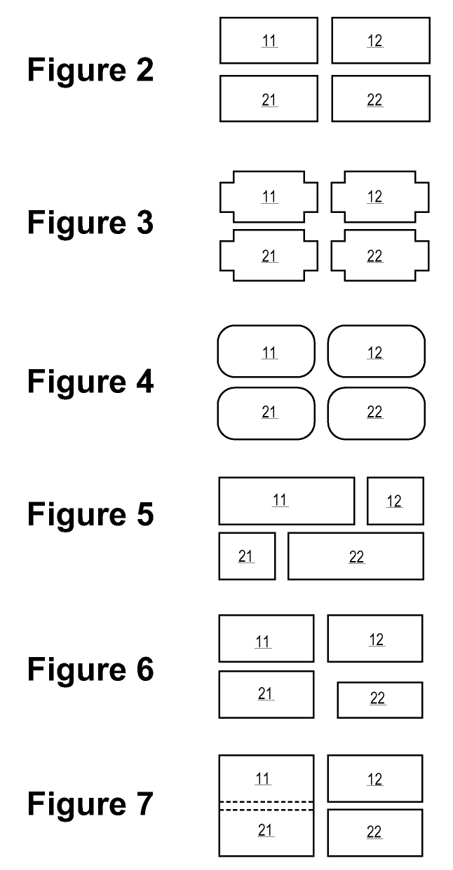

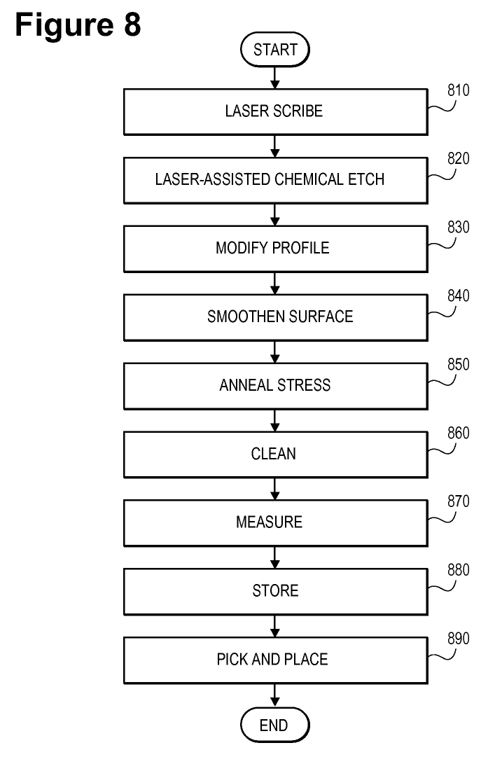

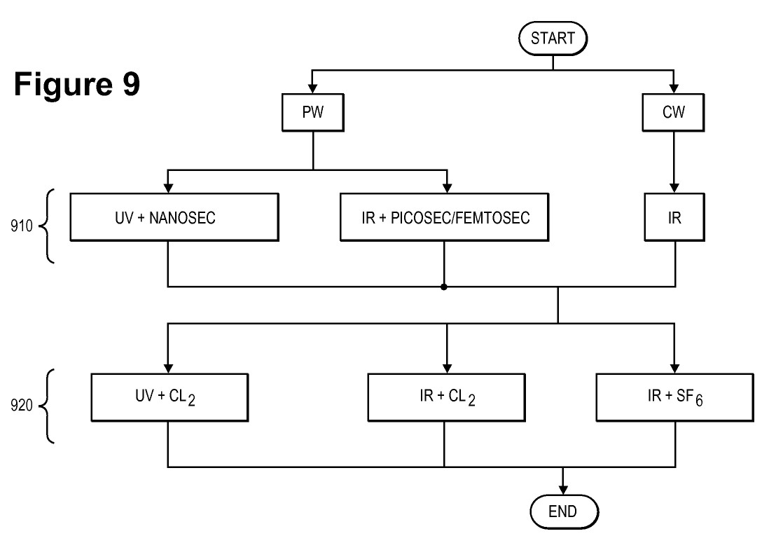

An apparatus 10 (as shown in FIG. 1) for, a method (as shown in FIGS. 8-9) of, and the resultant structures (as shown in FIGS. 2-7) formed by laser scribing and laser-assisted chemical singulation, such as along scribelines or streets of a substrate, and such as in high volume manufacturing (HVM), according to various embodiments of the present invention will be described below.

In an embodiment of the present invention as shown in FIG. 1, the substrate 300 includes a whole wafer. In an embodiment of the present invention, the substrate 300 includes a 200 mm diameter wafer with a thickness of 670-780 um. In an embodiment of the present invention, the substrate 300 includes a 300 mm diameter wafer with a thickness of 720-830 um. In an embodiment of the present invention, the substrate 300 includes a 450 mm diameter wafer with a thickness of 870-980 um.

In an embodiment of the present invention, the substrate 300 includes a device wafer that is bonded to a handle wafer, one of which is thinned from its backside. In an embodiment of the present invention, the substrate 300 includes silicon-on-insulator (SOI).

In an embodiment of the present invention, the substrate 300 includes a partial wafer with an irregular size and shape. In an embodiment of the present invention, the substrate 300 includes a quadrant of a wafer, such as of a 450 mm diameter wafer.

In an embodiment of the present invention, the substrate 300 includes a wafer that is attached to an interposer, a redistribution layer (to redistribute power and ground contacts), a redistribution layer (to transform off-chip connections from chip scale to board scale), a printed circuit board (PCB), a chip-scale package (CSP), a wafer-level package (WLP), a wafer-level chip-scale package, a 3-D package, or a system-in-package (SiP).

In an embodiment of the present invention, the substrate 300 includes an underfill, such as between a flip chip and an organic substrate.

In an embodiment of the present invention, the substrate 300 includes a hermetic passivation layer, such as silicon nitride or polyimide.

In an embodiment of the present invention, the substrate 300 includes 2 wafers, one of which is thinned and bumped on its backside, that are stacked front-to-front. In an embodiment of the present invention, the substrate 300 includes Cu-to-Cu diffusion bonded interfaces such as formed by thermocompression.

In an embodiment of the present invention, the substrate 300 includes 3 or more wafers, all of which are thinned on their backside except for one wafer, that are stacked front-to-back. In an embodiment of the present invention, the substrate 300 includes through-silicon-via (TSV) such as formed by deep reactive ion etch (DRIE).

In an embodiment of the present invention, the substrate 300 includes die stacked over wafers.

In an embodiment of the present invention, the substrate 300 includes die stacked over die.

Many structures, such as die, are formed on the frontside of the substrate 300. In an embodiment of the present invention, the substrate 300 includes die that measure 0.3-5.0 mm on each side. In an embodiment of the present invention, the substrate 300 includes die that measure 5.0-20.0 mm on each side. In an embodiment of the present invention, the substrate 300 includes die that measure 20.0-40.0 mm on each side. The die are organized into rows and columns delineated by scribelines and streets.

Next, thinning, scribing, and dicing of the substrate 300 according to embodiments of the present invention will be described.

First, in an embodiment of the present invention, a backside of the substrate 300 is thinned, such as by grinding and polishing, to reduce the thickness that needs to scribed and diced. In an embodiment of the present invention, the backside of the substrate 300 is thinned to 75-125 um. In an embodiment of the present invention, the backside of the substrate 300 is thinned to 25-75 um. In an embodiment of the present invention, the backside of the substrate 300 is thinned to 10-25 um.

In an embodiment of the present invention, the substrate 300 is mounted in a holder (not shown) before thinning the backside.

Second, in an embodiment of the present invention, 0-2 backside layers, such as a metallic material, are formed on the backside of the substrate 300 after thinning, to provide one or more functions, such as mechanical support, ease of handling (such as clamping), scratch protection, diffusion barrier, thermal conductivity, electrical conductivity, or absorption of light energy. The backside layers may include blanket films or patterned films. Some or all of the layers formed on the backside of the substrate 300 may be partly or entirely removed after singulation.

Third, in an embodiment of the present invention, the substrate 300 is mounted in a tape frame (not shown). The tape frame is made of plastic or metal and is rigid, stiff, heat-resistant, and corrosion-resistant.

Fourth, in an embodiment of the present invention, the backside of the substrate 300 and the tape frame are attached smoothly to an adhesive side of a tape or film (not shown) without trapping air bubbles. In an embodiment of the present invention, the die attach film (DAF) is a flexible and tough thermoplastic material that has a thermal conductivity of greater than 6.0 W/m-K and can withstand a temperature of 275 degrees Centigrade. In an embodiment of the present invention, the DAF is made of a 3.5-10.0 mils thick polyvinyl chloride (PVC) base film that is coated with a 0.3-1.1 mils thick pressure-sensitive epoxy adhesive and protected with a 0.8-1.0 mils thick release film.

Fifth, the die are partially separated (scribed) from their immediate neighboring die by cutting shallow trenches into the frontside of the substrate 300. In an embodiment of the present invention, laser scribing includes a single wide and shallow trench along the center of the scribelines. In an embodiment of the present invention, laser scribing includes two parallel separated narrow and shallow trenches along the edges of the scribelines.

In an embodiment of the present invention, 0-2 frontside layers, such as a water-soluble flux. or a temperature-resistant material, are coated on the frontside of the substrate 300 before laser-assisted chemical etch, to provide one or more functions, such as mask for etch, shield from etch debris, or protection from handling damage. The frontside layers may include blanket films or patterned films. Some or all of the layers formed on the frontside of the substrate 300 may be partly or entirely removed during or after wafer singulation.

Sixth, according to an embodiment of the present invention, the die are completely separated (diced) from their immediate neighboring die by cutting completely through the substrate 300 from the frontside. In an embodiment of the present invention, wafer dicing includes a single wide and deep trench along the center of the scribelines.

In an embodiment of the present invention, wafer dicing removes bulk material, such as Silicon, from the remaining thickness of the substrate 300 by a process of ablation.

Wafer dicing is also known as wafer singulation. In an embodiment of the present invention, wafer dicing removes bulk material, such as Silicon, from the remaining thickness of the substrate 300 by a process of laser-assisted chemical etching.

In an embodiment of the present invention, laser-assisted chemical singulation with an etch chemical is performed on the frontside of the thinned substrate 300 that has been mounted on the tape frame (not shown) and attached to the die attach film (not shown).

In an embodiment of the present invention, the laser-assisted chemical singulation is coatless since the frontside layer is not needed to cover solder bumps protruding from the frontside of the substrate 300.

In an embodiment of the present invention, the laser-assisted chemical singulation is maskless since the frontside layer is not needed to pattern the wafer for scribing or dicing.

Next, laser scribing and laser-assisted chemical etching of a substrate 300, such as a wafer, to separate out smaller structures, such as die, having various dimensions and shapes according to embodiments of the present invention will be described. In an embodiment of the present invention, the substrate 300 includes stacked wafers, die stacked on wafers, stacked die, and wafer-level packages.

As shown in an embodiment of the present invention in FIG. 2, laser scribing and laser-assisted chemical etching are used to separate four adjacent die 11, 12, 21, 22, such as at an intersection, by removing material between them along the scribelines and street in both the x- and the y-axes.

As shown in an embodiment of the present invention in FIG. 3, laser scribing and laser-assisted chemical etching are used to singulate die and shape the corners, such as by including notches.

As shown in an embodiment of the present invention in FIG. 4, laser scribing and laser-assisted chemical etching are used to singulate die and shape the edges, such as to become curved or rounded.

As shown in an embodiment of the present invention in FIG. 5, laser scribing and laser-assisted chemical etching are used to singulate die with scribelines and street that are irregular, such as having jogs or steps and thus not aligned in a straight line and, such as having different widths in the x-axis and the y-axis.

As shown in an embodiment of the present invention in FIG. 6, laser scribing and laser-assisted chemical etching are used to singulate die having different sizes and shapes, such as by adjusting the location and width of the scribelines and streets.

As shown in an embodiment of the present invention in FIG. 7, laser scribing and laser-assisted chemical etching are used to singulate known good die (KGD) 12, 22 while bypassing bad die 11, 21 by not singulating the bad die (shown as dashed lines).

Next, a singulation apparatus 10 according to the present invention that performs laser scribing and laser-assisted chemical etching will be described. In an embodiment of the present invention as shown in FIG. 1, a substrate transport mechanism 430 transfers the mounted substrate 300 and tape frame from a cartridge, cassette, or magazine in and out of the singulation apparatus 10. In an embodiment of the present invention, the singulation apparatus 10 includes two substrate transport mechanisms 430 to improve throughput and tool uptime.

In an embodiment of the present invention, the substrate transport mechanism 430 includes a series of interconnected belts or tracks. In an embodiment of the present invention, the belts or tracks move the mounted substrate 300 and tape frame into and out of the enclosure 1000. Other mounted substrates 300 and tape frames wait or move on other parts of the belts or tracks, such as in one or more queues, to be transferred or processed.

In an embodiment of the present invention, the substrate transport mechanism 430 includes a series of interconnected elevators. In an embodiment of the present invention, the elevators raise and lower the mounted substrate 300 and tape frame inside the enclosure 1000.

In an embodiment of the present invention, the substrate transport mechanism 430 includes a series of interconnected robots. In an embodiment of the present invention, the robots load and unload the mounted substrate 300 and tape frame from a chuck 432 inside the singulation apparatus 10.

In an embodiment of the present invention, the singulation apparatus 10 is designed, constructed, and assembled to be modular to accommodate high volume manufacturing (HVM). In an embodiment of the present invention, the singulation apparatus 10 has different configurations depending on various factors, such as operator safety, footprint size, module flexibility, adequate support for thinned substrates without damage (such as warpage or stress), and space for steering and scanning laser beams.

In an embodiment of the present invention, the chuck 432 includes a horizontal carousel (platter) or a horizontal susceptor to accommodate high volume manufacturing. In an embodiment of the present invention, the substrate 300 faces downwards in the horizontal carousel (platter) or the horizontal susceptor (so a laser beam points upwards). In an embodiment of the present invention, the substrate 300 faces upwards in the horizontal carousel (platter) or the horizontal susceptor (so a laser beam points downwards).

In an embodiment of the present invention, the chuck 432 includes a vertical carousel (platter) or a vertical susceptor to accommodate high volume manufacturing. In an embodiment of the present invention, the substrate 300 faces inwards in the vertical carousel (platter) or the vertical susceptor (so the laser beam points outwards). In an embodiment of the present invention, the substrate 300 faces outwards in the vertical carousel (platter) or the vertical susceptor (so a laser beam points inwards).

In an embodiment of the present invention, the horizontal carousel (platter), the vertical carousel (platter), the horizontal susceptor, or the vertical susceptor are designed to hold multiple mounted substrates 300 and tape frames, depending on the size and shape of the substrate 300. In an embodiment of the present invention, the multiple mounted substrates 300 having different sizes and shapes are processed in the singulation apparatus 10.

In an embodiment of the present invention, the vertical susceptor has a polygonal cross-section. In an embodiment of the present invention, the vertical susceptor includes 5-8 vertical faces arranged horizontally around a vertical axis. In an embodiment of the present invention, the vertical susceptor includes 1-4 tiers arranged vertically on each face.

In an embodiment of the present invention, the chuck 432 is mounted on a stage 434 in the process chamber 1010 of the singulation apparatus 10. In an embodiment of the present invention, the stage 434 includes a horizontal or a vertical table. In an embodiment of the present invention, the stage 434 is rigid and isolated from sources of vibration.

In an embodiment of the present invention, the stage 434 shifts, raises, lowers, rotates, and tilts the chuck 432 in the process chamber 1010 by using collaborative actuators, with feedback from corresponding sensors, to iteratively locate, position, orient, and align the mounted substrate 300 and frame, to predetermined tolerances, for laser-assisted chemical etch. In an embodiment of the present invention, the stage 434 includes an indexing accuracy of 1.0 um and a rotary accuracy of 4.0 arc-sec.

In an embodiment of the present invention, the stage 434 is shifted (translated) with high-speed servo motors and linear encoders connected to HeNe laser interferometers. In an embodiment of the present invention, the stage 434 is raised or lowered with motors and piezoelectric transducers (PZT). In an embodiment of the present invention, the stage 434 is rotated with motors and rotary encoders. In an embodiment of the present invention, the stage 434 is leveled or tilted by motors and actuators.

In an embodiment of the present invention, the singulation apparatus 10 includes at least one process chamber 1010 inside the enclosure 1000. During operation, the process chamber 1010 is sealed off from an environment surrounding the enclosure 1000.

In an embodiment of the present invention, the mounted substrate 300 and frame are held by the chuck 432 in the process chamber 1010 of the singulation apparatus 10.

In an embodiment of the present invention, the chuck 432 includes a clamp to hold the mounted substrate 300 and frame. In an embodiment of the present invention, the chuck 432 includes a vacuum chuck to hold the mounted substrate 300 and frame. In an embodiment of the present invention, the chuck 432 includes an electrostatic chuck to hold the mounted substrate 300 and frame, such as when the process chamber 1010 is under vacuum.

In an embodiment of the present invention, an illumination mechanism 110 produces electromagnetic radiation, such as light, from a source in the singulation apparatus 10. In an embodiment of the present invention, the illumination mechanism 110 expands, filters, homogenizes, shapes, and directs the light, such as in a laser beam 200, towards the mounted substrate 300 and frame held by the chuck 432 in the process chamber 1010 in the enclosure 1000.

In an embodiment of the present invention, the illumination mechanism 110 is located inside the enclosure 1000, but outside the process chamber 1010. The laser beam 200 is transmitted through a window into the process chamber 1010 of the enclosure 1000. The window is formed from a material that is transparent to the wavelengths of light from the laser beam 200.

In an embodiment of the present invention, cut-off wavelengths for far-ultraviolet (FUV) long pass filters are 155.0 nm for Al₂O₃, 134.5 nm for BaF₂, 131.0 nm for SrF₂, 122.5 nm for CaF₂, 112.0 nm for MgF₂, and 103.5 nm for LiF. In an embodiment of the present invention, transmission curves for alkali halide crystals shift to longer wavelengths as temperature increases. The reverse is also true since the transmission curves for alkali halide crystals shift to shorter wavelengths as the temperature decreases.

In an embodiment of the present invention, a focusing mechanism 120 focuses the laser beam 200, such as in a direction perpendicularly towards the outer surface of the mounted substrate 300 and frame. In an embodiment of the present invention, the focusing mechanism 120 includes a plano-convex lens. In an embodiment of the present invention, the focusing mechanism 120 includes a cylindrical lens. In an embodiment of the present invention, the focusing mechanism 120 includes an f-theta lens.

In an embodiment of the present invention, the focusing mechanism 120 has a focal length (F.L.) of 10-25 mm with a depth of focus of ±0.5 mm. In an embodiment of the present invention, the focusing mechanism 120 has a focal length of 25-60 mm with a depth of focus of ±1.0 mm. In an embodiment of the present invention, the focusing mechanism 120 has a focal length of 60-150 mm with a depth of focus of ±3.0 mm. In an embodiment of the present invention, the focusing mechanism 120 has a focal length of 150-375 mm with a depth of focus of ±7.5 mm.

In an embodiment of the present invention, a steering mechanism 130 steers the laser beam 200, such as along an outer surface of the substrate 300. In an embodiment of the present invention, a galvanometer (galvo) mirror provides y-deflection while another galvanometer (galvo) mirror provides x-deflection.

In an embodiment of the present invention, the galvano mirror type scanner has a minimum spatial resolution of 0.6-1.8 nm per step. In an embodiment of the present invention, the galvano mirror type scanner has a minimum spatial resolution of 6-15 um. In an embodiment of the present invention, the galvano mirror type scanner has a minimum spatial resolution of 15-30 um.

In an embodiment of the present invention, the focusing mechanism 120 and the steering mechanism 130 are electronically coupled through a closed-loop system to dynamically focus (on the fly) and move the laser beam 200 in real time, such as during laser-assisted chemical etch.

In an embodiment of the present invention, the laser beam 200 has a working area of 500×250 mm² in the plane of the mounted substrate 300 and frame. In an embodiment of the present invention, the laser beam 200 has a working area of 400×300 mm² in the plane of the mounted substrate 300 and frame. In an embodiment of the present invention, the laser beam 200 has a working area of 350×350 mm² in the plane of the mounted substrate 300 and frame.

In an embodiment of the present invention, an optical scanning mechanism 140 scans the laser beam 200 across an outer surface of the mounted substrate 300 and frame held on the chuck 432 which is mounted on the stage 434 that is stationary.

In an embodiment of the present invention, the optical scanning mechanism 140 has a scanning speed of 50-200 mm/sec. In an embodiment of the present invention, the optical scanning mechanism 140 has a scanning speed of 200-600 mm/sec. In an embodiment of the present invention, the optical scanning mechanism 140 has a scanning speed of 600-1,200 mm/sec.

In an embodiment of the present invention, the laser beam 200 is operated in a vector scan mode. In an embodiment of the present invention, the laser beam 200 is switched off between scans. In an embodiment of the present invention, the switching includes mechanical, optical, electro-optical, magneto-optical, or acousto-optical switching.

In an embodiment of the present invention, the laser beam 200 is operated in a raster scan mode. In an embodiment of the present invention, the laser beam 200 is blanked out as needed (without switching it off) by using a shutter, a deflection plate, or a mirror.

In an embodiment of the present invention, a mechanical scanning mechanism 440 scans the stage 434, on which the chuck 432 is mounted, under a laser beam 200 that is stationary.

In an embodiment of the present invention, the mechanical scanning mechanism 440 has a scanning speed of 50-200 mm/sec. In an embodiment of the present invention, the mechanical scanning mechanism 440 has a scanning speed of 200-600 mm/sec. In an embodiment of the present invention, the mechanical scanning mechanism 440 has a scanning speed of 600-1,200 mm/sec.

In an embodiment of the present invention, the optical scanning mechanism 140 and the mechanical scanning mechanism 440 are coupled through a close-loop system to scan both the laser beam 200 and the stage 434, on which the chuck 432 is mounted. In an embodiment of the present invention, the closed-loop system mixes beat frequencies and prevents standing waves. In an embodiment of the present invention, the closed-loop system improves uniformity of the laser-assisted chemical etch.

In an embodiment of the present invention, a first computer 100 controls the optical subsystems of the singulation apparatus 10, such as the illumination mechanism 110, the focusing mechanism 120, the steering mechanism 130, and the optical scanning mechanism 140.

In an embodiment of the present invention, a second computer 400 controls the mechanical subsystems of the singulation apparatus 10, such as the substrate transport mechanism 430 and the mechanical scanning mechanism 440.

Both computers 100, 400 are accessed through a user interface 505 with menu-driven software 500.

In an embodiment of the present invention, a third computer (not shown) communicates with both the first computer 100 and the second computer 400.

In an embodiment of the present invention, the third computer coordinates the singulation apparatus 10 with other singulation apparatus (not shown) to apportion work among them more efficiently, such as to minimize queue time in HVM.

In an embodiment of the present invention, the third computer coordinates the singulation apparatus 10 with other equipment (not shown) that are upstream or downstream of the singulation apparatus 10 to improve flow, such as to reduce size of incoming inventory or outgoing inventory in HVM.

In an embodiment of the present invention as shown in FIG. 9, the laser beam 200 is from a continuous wave (CW) laser.

In an embodiment of the present invention, the CW laser beam 200 has a power of 70-500 milliWatt. In an embodiment of the present invention, the laser beam 200 has a power of 0.5-3.0 Watt. In an embodiment of the present invention, the laser beam 200 has a power of 3.0-15.0 Watt. In an embodiment of the present invention, the laser beam 200 has a power of 15.0-60.0 Watt.

In an embodiment of the present invention, the laser beam 200 is p-polarized, i.e., the electric field vector of the laser beam 200 oscillates parallel to the plane of the incidence of the laser beam 200. In an embodiment of the present invention, the laser beam 200 is s-polarized, i.e., the electric field vector of the laser beam 200 oscillates perpendicular to the plane of the incidence of the laser beam 200. In an embodiment of the present invention, the laser beam 200 is circular polarized. Fresnel refraction depends on polarization.

In an embodiment of the present invention, the laser beam 200 is from a lamp-pumped or diode-pumped solid-state (DPSS) laser. The DPSS laser produces excellent beam quality, high repetition rate, and small beam size.

In an embodiment of the present invention, the laser beam 200 is from a DPSS laser, such as a CW neodymium-doped yttrium aluminum garnet (Nd³⁺/Y₃Al₅O₁₂ or Nd:YAG) laser. In an embodiment of the present invention, the laser beam 200 has a wavelength of 1,064 nm, 532 nm, 355 nm, or 266 nm.

In an embodiment of the present invention, the laser beam 200 is from a DPSS laser, such as a CW neodymium-doped yttrium lithium fluoride (Nd³⁺/YLiF₄ or Nd:YLF) laser. In an embodiment of the present invention, the laser beam 200 has a wavelength of 1,053 nm, 527 nm, 351 nm, or 263 nm.

In an embodiment of the present invention, the laser beam 200 is from an argon ion Ar⁺ CW laser producing illumination having multiple wavelengths, including 514.5 nm, 497.0 nm, 488.0 nm, 476.5 nm, 457.9 nm, 363.8 nm, 351.0 nm, and 334.0 nm.

In another embodiment of the present invention as shown in FIG. 9, the laser beam 200 is from a pulsed wave (PW) laser.

In an embodiment of the present invention, the PW laser beam 200 has a pulse energy of 1-15 mJ. In an embodiment of the present invention, the PW laser beam 200 has a pulse energy of 15-200 mJ. In an embodiment of the present invention, the PW laser beam 200 has a pulse energy of 200-2,200 mJ.

In an embodiment of the present invention, the laser beam 200 has a pulse repetition rate of 0.15-2.00 kHz. In an embodiment of the present invention, the laser beam 200 has a pulse repetition rate of 2.0-22.0 kHz. In an embodiment of the present invention, the laser beam 200 has a pulse repetition rate of 22.0-200.0 kHz. In an embodiment of the present invention, the laser beam 200 has a pulse repetition rate of 0.2-1.4 MHz. In an embodiment of the present invention, the laser beam 200 has a pulse repetition rate of 1.4-7.0 MHz.

In an embodiment of the present invention as shown in FIG. 9, the PW laser is a nanosecond laser. In an embodiment of the present invention, the laser beam 200 has a pulse width of 1-6 ns. In an embodiment of the present invention, the laser beam 200 has a pulse width of 6-24 ns. In an embodiment of the present invention, the laser beam 200 has a pulse width of 24-85 ns. In an embodiment of the present invention, the laser beam 200 has a pulse width of 85-255 ns.

In an embodiment of the present invention, a longer pulse width results in a higher laser assisted chemical etch rate. In an embodiment of the present invention, a shorter pulse width results in a lower temperature rise during the laser assisted chemical etch. In an embodiment of the present invention, the pulse width is varied to optimize etch uniformity of the laser-assisted chemical etch.

In an embodiment of the present invention, the laser beam 200 is from a CO₂ PW laser producing illumination having a wavelength of 10.64 um which corresponds to a frequency of 2.8×10¹³ Hz.

In an embodiment of the present invention, the laser beam 200 is from an ultraviolet (UV) light laser.

In an embodiment of the present invention, the laser beam 200 is from an excimer laser. In an embodiment of the present invention, the laser beam 200 has a wavelength of 351 nm (XeF). In an embodiment of the present invention, the laser beam 200 has a wavelength of 308 nm (XeCl). In an embodiment of the present invention, the laser beam 200 has a wavelength of 248 nm (KrF). In an embodiment of the present invention, the laser beam 200 has a wavelength of 193 nm (ArF). In an embodiment of the present invention, the laser beam 200 has a wavelength of 157 nm (F₂).

Excimer lasers produce high pulse energy, but at low repetition rates, such as 1-100 pulses per second, with beams having low optical quality.

In an embodiment of the present invention as shown in FIG. 9, the laser beam 200 is from an ultrafast laser, such as a picosecond laser or a femtosecond laser, to provide temporal confinement. A pulse with a fast rise time (square wave pulse) and a short duration creates less heat during the pulse and permits more of the heat to dissipate between consecutive pulses.

In an embodiment of the present invention, the laser beam 200 is from a picosecond laser with a pulse width of 5-35 (10⁻¹²) picoseconds. In an embodiment of the present invention, the laser beam 200 is from a picosecond laser with a pulse width of 35-175 (10⁻¹²) picoseconds. In an embodiment of the present invention, the laser beam 200 is from a picosecond laser with a pulse width of 175-525 (10⁻¹²) picoseconds.

In an embodiment of the present invention, the laser beam 200 is a femtosecond laser with a pulse width of 5-35 (10⁻¹⁵) femtoseconds. In an embodiment of the present invention, the laser beam 200 is a femtosecond laser with a pulse width of 35-175 (10⁻¹⁵) femtoseconds. In an embodiment of the present invention, the laser beam 200 is a femtosecond laser with a pulse width of 175-525 (10⁻¹⁵) femtoseconds.

In an embodiment of the present invention, the laser beam 200 has a shape of an ellipse in cross-section. In an embodiment of the present invention, the laser beam 200 has a ratio of major axis: minor axis of 1:1 (circle). In an embodiment of the present invention, the laser beam 200 has a ratio of major axis:minor axis is (2-3):1. In an embodiment of the present invention, the laser beam 200 has a ratio of major axis: minor axis is (5-10):1.

In an embodiment of the present invention, the major axis is oriented across and parallel to a width of the laser-assisted cut along the scribeline or street. In an embodiment of the present invention, the minor axis is oriented across and parallel to a width of the laser-assisted cut along the scribeline or street.

In an embodiment of the present invention, the laser beam 200 is scanned parallel to the major axis. In an embodiment of the present invention, the laser beam 200 is scanned parallel to the minor axis. In an embodiment of the present invention, the laser beam 200 is partially scanned parallel to the major axis and partially scanned parallel to the minor axis.

In an embodiment of the present invention, the laser beam 200 has a spot size that is adjustable. In an embodiment of the present invention, the spot size is controlled by the focusing mechanism 120.that adjusts the focal length of the laser beam 200. In an embodiment of the present invention, the spot size is controlled by the mechanical scanning mechanism 440 that adjusts a height, or separation, of the stage 434, on which the chuck 432 is mounted. In an embodiment of the present invention, the spot size is adjusted with a cylindrical lens.

In an embodiment of the present invention, the laser beam 200 has a single-mode output with an intensity profile that depends on how the light is confined. The modes are quantized so only certain modes are allowed. In an embodiment of the present invention, the boundary conditions imposed on a plane wave propagating through free space, such as the light in the laser beam 200, results in an intensity profile with a transverse (perpendicular to a direction of propagation) pattern that has cylindrical symmetry. When a radial mode order p=0 (concentric ring of intensity) and an angular mode order, or index, I=0 (angularly distributed lobe), the TEM_{pI} mode becomes TEM₀₀ which is the lowest-order, or fundamental, transverse electromagnetic mode. The TEM₀₀ mode has the same form as a Gaussian beam with a single lobe, and thus a constant phase, across the mode. During propagation, the TEM₀₀ mode of the laser beam 200 may increase or decrease in overall size, but preserves its general shape. Other higher-order modes have a relatively larger spatial extent than the TEM₀₀ mode (which is relatively the smallest).

In an embodiment of the present invention, the laser beam 200 has a shape of a circle in cross-section. In an embodiment of the present invention, the laser beam 200 has a spot size (diameter) of 45-90 um. In an embodiment of the present invention, the laser beam 200 has a spot size (diameter) of 15-45 um. In an embodiment of the present invention, the laser beam 200 has a spot size (diameter) of 4-15 um. In an embodiment of the present invention, the laser beam 200 has a spot size (diameter) that is limited by diffraction.

In an embodiment of the present invention, the laser beam 200 has a fixed spot size on the outer surface of the mounted substrate 300 during operation. In an embodiment of the present invention, the laser beam 200 has a variable spot size on the outer surface of the mounted substrate 300 during operation.

In an embodiment of the present invention, the laser beam 200 impinges on the outer surface of the mounted substrate 300 with an incident angle of 87-93 degrees. In an embodiment of the present invention, the laser beam 200 impinges on the outer surface of the mounted substrate 300 with an incident angle of 84-96 degrees. In an embodiment of the present invention, the laser beam 200 impinges on the outer surface of the mounted substrate 300 with an incident angle of 78-102 degrees.

In an embodiment of the present invention, multiple laser beams are separated out by beamsplitting apparatus from a laser beam 200 generated by a single source of illumination.

In an embodiment of the present invention, multiple laser beams are generated separately from one or more sources of illumination. In an embodiment of the present invention, several transparent windows permit multiple laser beams to enter the process chamber 1010.

In an embodiment of the present invention, the laser-assisted chemical etch includes multiple laser beams 200 that are linked by hardware into one or more gangs which increases throughput when processing parallel rows in a substrate 300.

In an embodiment of the present invention, the laser-assisted chemical etch includes two or more separate laser beams that are multiplexed by software. In an embodiment of the present invention, the separate laser beams have similar properties. In an embodiment of the present invention, the separate laser beams have different properties.

In an embodiment of the present invention, a continuous wave laser beam and a pulsed wave laser beam overlap each other spatially to process a substrate 300.

In an embodiment of the present invention, a continuous wave laser beam and a pulsed wave laser beam overlap each other temporally to process a substrate 300.

In an embodiment of the present invention, a continuous wave laser beam and a pulsed wave laser beam do not overlap each other, spatially or temporally, to process a substrate 300.

In an embodiment of the present invention, multiple laser beams interfere destructively, at least in part, to permit a smaller resolution to be achieved.

In an embodiment of the present invention as shown in FIG. 9, a continuous wave (CW) infrared (IR) wavelength laser beam performs laser scribing 910 with a shallow etch though overlying non-Silicon layers, such as having a thickness of 10-15 um, at or near the surface. In an embodiment of the present invention, a pulse wave (PW) ultraviolet (UV) wavelength laser beam performs laser-assisted chemical etching with a through cut of the remaining thickness of underlying bulk Silicon below the surface in the substrate 300.

In an embodiment of the present invention, the CW IR laser beam is tilted, such as at 60(±20) degrees off-normal, relative to the outer surface of the substrate 300 to avoid a plasma plume which is perpendicular (normal) relative to the outer surface of the substrate 300.

In an embodiment of the present invention, the CW IR laser beam is tilted at a Brewster angle, such as 74 degrees off-normal for a bare Silicon wafer, to minimize loss of laser power due to reflection off the outer surface of the substrate 300.

In an embodiment of the present invention, the PW UV laser beam is normal or overhead, such as at 0(±20) degrees off-normal, relative to the outer surface of the substrate 300.

In an embodiment of the present invention, most, if not all, of the substrate 300 is laser scribed 910 before it is laser-assisted chemically etched 920.

In an embodiment of the present invention, the CW IR laser beam and the PW UV laser beam are connected by hardware and software into a gang, such that the CW IR laser beam leads, such as to perform laser scribing 910, and the PW UV laser beam follows, such as to perform laser-assisted chemical etching 920, on the same structure, such as the die, on the substrate 300. Thus, laser scribing and laser-assisted chemical singulation are performed sequentially with a very small time interval between them.

Next, various processes to perform laser scribe of the substrate 300, such as in the singulation apparatus 10, will be described.

In an embodiment of the present invention as shown in FIG. 9, laser scribing 910 removes surface layers, such as metal and oxide, with a thickness of 10-15 um, from the substrate 300 by a process of ablation. In an embodiment of the present invention, laser scribing removes test element groups (TEG) and metal pads that are located in the scribelines between adjacent die. In an embodiment of the present invention, laser scribing is performed on the thinned substrate 300 that has been mounted on the tape frame and attached to the die attach film.

In general, energy of a photon increases as wavelength of light decreases. In particular, photon energy is 3.5 electron Volts (eV) for a wavelength of 355 nm, such as produced by a Nd:YAG laser. In particular, photon energy is 4.7 electron Volts (eV) for a wavelength of 266 nm such as produced by a Nd:YAG laser. In particular, photon energy is 5.0 electron Volts (eV) for a wavelength of 248 nm, such as produced by a KrF laser. In particular, photon energy is 7.9 electron Volts (eV) for a wavelength of 157 nm, such as produced by a F₂ laser.

A band gap of a material refers to an energy difference between a top of a valence band and a bottom of a conduction band. Electrons that gain energy by absorbing phonons (heat) or photons (light) can become excited enough to jump across the band gap and become carriers for electrical conduction.

A material with a small band gap, such as less than 3.0 eV, is considered to be a semiconductor. In an embodiment of the present invention, Germanium is an elemental semiconductor with a band gap, E_{g}, of 0.67 eV at a temperature of 300 K. In an embodiment of the present invention, Silicon is an elemental semiconductor with a band gap, E_{g}, of 1.12 eV at a temperature of 300 K. In an embodiment of the present invention, Gallium Arsenide is a III-V compound semiconductor with a band gap, E_{g}, of 1.43 eV at a temperature of 300 K. In an embodiment of the present invention, Silicon Carbide is a semiconductor with a band gap, E_{g}, of 2.86 eV at a temperature of 300 K. In an embodiment of the present invention, Silicon Germanium (SiGe) is a semiconductor with a band gap of 0.35-0.65 eV upon application of a uniaxial (applied in the channel direction) compressive stress.

A material with a large band gap, such as greater than 3.0 eV, is considered to be an electrical insulator. In an embodiment of the present invention, Silicon Nitride is an insulator with a band gap, E_{g}, of 5.0 eV at a temperature of 300 K. In an embodiment of the present invention, Diamond is a form of Carbon insulator with a band gap, E_{g}, of 5.5 eV at a temperature of 300 K. In an embodiment of the present invention, Silicon Dioxide is a form of insulator with a band gap, E_{g}, of 9.0 eV at a temperature of 300 K.

A material with a band gap that is smaller than a photon energy of a laser is opaque (low ablation threshold) and is ablated by the laser when enough incident energy is absorbed by the lattice to induce heating, melting, and evaporation of the material. However, a material with a band gap that is larger than the photo energy is transparent (high ablation threshold) and is not ablated by the laser since most of the incident energy is transmitted rather than absorbed.

In an embodiment of the present invention, the laser scribing is performed with a laser beam 200 with a wavelength of 355 nm (ultraviolet), a pulse width of 10-120 nsec, a pulse energy of 30-125 uJ, a repetition rate of 30-150 kHz, consecutive pass overlapping of 65-85%, and a stage scanning speed of 25-200 mm/sec.

As shown in block 910 in an embodiment of the present invention in FIG. 9, laser scribing with nanosecond pulses of light, such as with a short ultraviolet wavelength of less than 400 nm, achieves ablation of materials through a physical process that thermally heats, melts, and evaporates the materials. However, the large temperature rise enlarges the heat affected zone (HAZ), increases stress, increases micro-cracking, increases delamination, increases deposition of debris on the surface, and increases deposition of recast material in the cut (trench). In an embodiment of the present invention, laser scribing with nanosecond pulses is limited to a substrate 300 with a thickness of greater than 50 um since die strength is significantly reduced.

In an embodiment of the present invention, the laser scribing is performed with a laser beam 200 with a wavelength of 1,064 nm (infrared), a pulse width of 1-15 psec, a pulse energy of 10-40 uJ, a repetition rate of 30-150 kHz, consecutive pass overlapping of 65-85%, and a stage scanning speed of 1-15 mm/sec.

As shown in block 910 in an embodiment of the present invention in FIG. 9, laser scribing with picosecond or femtosecond pulses of light, such as with a long infrared wavelength of 700-1,500 nm, achieves ablation of materials through an intense optical field that excites and breaks atomic bonds in the materials. Electrons in the conduction band (or in defect states below the conduction band) are excited to the vacuum level, thus ablating the material. Picosecond or femtosecond pulses result in a lower temperature rise and allow laser scribing of a substrate 300 that has been thinned to even below 50 um since die strength is mostly preserved.

Next, various processes to perform laser-assisted chemical etch of the substrate 300, such as in the singulation apparatus 10, will be described.

A gas feed line 451 with a pump transports the etch chemical 452 to the process chamber 1010 in the singulation apparatus 10.

In an embodiment of the present invention, the etch chemical 452 is diluted with one or more types of carrier gas. In an embodiment of the present invention, the carrier gas is an inert gas, such as Helium (He), Argon (Ar), or Xenon (Xe).

In an embodiment of the present invention, Helium maximizes ionization potential of a gaseous mixture, suppresses plasma formation by a high-powered focused laser beam, minimizes attenuation of laser energy by interaction of the plasma with the laser beam, maximizes transmission of the laser beam through the gaseous mixture, and reduces localized thermal damage to the substrate 300.

In an embodiment of the present invention, the carrier gas is N₂. In an embodiment of the present invention, the carrier gas is H₂.

In an embodiment of the present invention, the inert gas diluent, such as Argon, alters the thermodynamics of the reaction of the etch chemical 452. In an embodiment of the present invention, the inert gas diluent, such as Argon, alters the kinetics of the reaction of the etch chemical 452. In an embodiment of the present invention, the laser assisted chemical cut with inert gas diluent results in a cut in the substrate 300 that is wider, less uniform, and more rounded in cross-section.

During operation, a mass flow controller adjusts a flow rate of the etch chemical 452 and the carrier gas into the process chamber 1010.

In an embodiment of the present invention, one or more nozzles dispense the etch chemical 452 and the carrier gas in continuous streams towards the mounted substrate 300 and frame held by the chuck 432.

In an embodiment of the present invention, one or more nozzles dispense the etch chemical 452 and the carrier gas in discontinuous pulses towards the mounted substrate 300 and frame held by the chuck 432.

In an embodiment of the present invention, one or more nozzles dispense volatile byproducts (not shown) of the reaction towards the mounted substrate 300 and frame held by the chuck 432 to slow down the etch process. In an embodiment of the present invention, the volatile byproducts of the reaction are produced in situ to achieve self-contained efficiency. In an embodiment of the present invention, the volatile byproducts of the reaction are produced ex situ to achieve decoupled flexibility.

In an embodiment of the present invention, one or more nozzles dispense volatile byproducts (not shown) of the reaction towards the mounted substrate 300 and frame held by the chuck 432 to reverse the etch process.

The etch chemical 452 is, directly or indirectly, induced by the laser beam 200 to etch the wafer 300. In an embodiment of the present invention, the etch is diffusion-limited or mass transfer-limited. In an embodiment of the present invention, the etch is reaction-limited. The reaction steps may be non-steady state (transient) or steady state. The reaction steps may be irreversible or reversible. The reaction steps may be serial or parallel. The reaction steps may compete with each other.

The laser-assisted chemical etch requires interaction of an etch chemical 452 and a laser beam 200 in the process chamber 1010. In an embodiment of the present invention, the interaction of the etch chemical 452 and the laser beam 200 in the process chamber 1010 is direct, such as in a line-of-sight in-situ photolytic process. In an embodiment of the present invention, the interaction of the etch chemical 452 and the laser beam 200 in the process chamber 1010 is indirect, such as in a downstream ex-situ thermolytic process.

In an embodiment of the present invention, the interaction of the etch chemical 452 and the laser beam 200 in the process chamber 1010 is alternately direct and indirect. In an embodiment of the present invention, the interaction of the etch chemical 452 and the laser beam 200 in the process chamber 1010 is sequentially direct and indirect. In an embodiment of the present invention, the interaction of the etch chemical 452 and the laser beam 200 in the process chamber 1010 is concurrently direct and indirect.

In an embodiment of the present invention, photolysis of molecules to produce reactive radicals may result from exciting multiple photons in a ground electronic state. In an embodiment of the present invention, photolysis of molecules to produce reactive radicals may result from exciting a single photon in an excited electronic state.

In an embodiment of the present invention, the dissociation of gaseous molecules may be induced by multiple photons in the infrared spectral region. In an embodiment of the present invention, the dissociation of gaseous molecules may be induced by a single photon in the ultraviolet and visible spectral region.

In various embodiments of the present invention, the etch chemical 452 includes BrCl, BrF, Cl₂, ClF₃, NF₃, OF₂, SF₆, or XeF₂. In an embodiment of the present invention, the etch chemical 452 includes a halocarbon, such as CF₂HCl. In an embodiment of the present invention, the etch chemical 452 includes an organometallic compound.

In an embodiment of the present invention, the etch chemical 452 includes Cl₂. Gaseous Cl₂ dissociates when exposed to light of sufficient intensity in the ultraviolet region (200-400 nm) or the shorter part of the visible region (400-500 nm) with a peak at about 330 nm. The gaseous Cl₂ does not dissociate when exposed to light in the longer part of the visible region (500-700 nm) or the infrared region (700 nm-1 mm).

In an embodiment of the present invention, irradiation of the gaseous Cl₂ with a Nd:YLF PW laser beam 200 having a wavelength of 351 nm results in dissociation into Cl radicals. In an embodiment of the present invention, the laser beam 200 produces pulses with a pulse width of 100 ns and a repetition rate of 8 kHz.

As shown in block 920 in an embodiment of the present invention in FIG. 9, laser-assisted chemical etch is performed with ultraviolet (UV) light and Chlorine (Cl₂).

In an embodiment of the present invention, when the wafer 300 is exposed to both the etch chemical 452 and light of 220-400 nm wavelength in a laser beam 200 with a fluence that is less than 100 mJ/cm², (regime 1) the wafer 300 will be etched at a rate that is almost linearly dependent on the fluence of the laser beam 200. In regime 1, the laser-assisted chemical etch includes discrete steps, such as diffusion of the etch chemical 452 in the process chamber 1010 to (or near) the wafer 300, (chemical) adsorption (chemisorption) of (some of) the etch chemical 452 to the wafer 300, absorption of energy from the laser beam 200 by the etch chemical 452 on (or near) the wafer 300, photolytic dissociation (or decomposition) of the etch chemical 452 on (or near) the wafer 300 to form radicals, transfer of photoelectrons to the radicals to produce ions, diffusion of the ions (and some of the radicals) about 8-10 nm into the wafer 300, breakage of the Si—Si bonds in the lattice of the wafer 300 by the ions (and some of the radicals), reaction of the ions (and some of the radicals) with the silicon in the wafer 300, formation of volatile (and non-volatile) byproducts on (or near) the wafer 300, desorption of the volatile byproducts from the wafer 300, and diffusion of the volatile byproducts away from the wafer 300.

As shown in block 920 in an embodiment of the present invention in FIG. 9, laser-assisted chemical etch is performed with infrared (IR) light and Chlorine (Cl₂).

In an embodiment of the present invention, when the wafer 300 is exposed to both the etch chemical 452 and light of 400-1,400 nm wavelength in a laser beam 200 with a fluence that is greater than 440 mJ/cm², (regime 3) the wafer 300 is etched at a rate that is highly non-linearly dependent on the fluence of the laser beam 200. In regime 3, the laser-assisted chemical etch includes discrete steps, such as diffusion of the etch chemical 452 in the process chamber 1010 to (or near) the wafer 300, (chemical) adsorption (chemisorption) of (some of) the etch chemical 452 to the wafer 300, absorption of energy from the laser beam 200 by the wafer 300, heating up of the wafer 300, thermolytic dissociation (or decomposition) of the etch chemical 452 on (or near) the wafer 300 to form radicals, transfer of photoelectrons to the radicals to produce ions, diffusion of the ions (and some of the radicals) about 8-10 nm into the wafer 300, excitation of the lattice of the wafer 300, breakage of the Si-Si bonds in the lattice of the wafer 300 by the ions (and some of the radicals), reaction of the ions (and some of the radicals) with the silicon in the wafer 300, formation of volatile (and non-volatile) byproducts on (or near) the wafer 300, desorption of the volatile byproducts from the wafer 300, and diffusion of the volatile byproducts away from the wafer 300.

In an embodiment of the present invention, when the wafer 300 is exposed to both the etch chemical 452 and light of 400-500 nm wavelength in a laser beam 200 with a fluence that is 100-440 mJ/cm², (regime 2) the wafer 300 is etched at a rate that is moderately non-linearly dependent on the fluence of the laser beam 200. In regime 2, the laser assisted chemical etch includes a combination of photolytic and thermolytic dissociation (or decomposition), such as on (or near) the wafer 300 to form radicals.

As shown in block 920 in an embodiment of the present invention in FIG. 9, laser-assisted chemical etch is performed with infrared (IR) light and Sulfur Hexafluoride (SF₆).

In an embodiment of the present invention, the etch chemical 452 includes SF₆. In an embodiment of the present invention, the SF₆ molecules are relatively inert to Silicon in the substrate 300. The SF₆ molecules do not chemisorb on the Silicon at room temperature. Only one monolayer of the SF₆ molecules will physisorb on the Silicon at 20 Torr. In an embodiment of the present invention, the SF₆ molecules have a vibrational relaxation time of less than 0.25 us at 2 Torr.

In an embodiment of the present invention, irradiation of the gaseous SF₆ with PW IR (10.64 um) CO2 laser beam results in multiphoton absorption and dissociation of SF₆ into SF₄ and atomic F. In an embodiment of the present invention, the laser beam 200 produces pulses with an intensity of 3.0-5.0 J/cm² and a shape having a half-width of 150 ns in a main pulse and 2 us in the tail.

In an embodiment of the present invention, irradiation of the gaseous SF₆ with a Nd:YAG CW laser beam 200 having a wavelength of 1,064 nm results in dissociation into F radicals.

In an embodiment of the present invention, solid Silicon in the substrate 300 scavenges SF₄ to produce SiF₄. In an embodiment of the present invention, the same amount of SiF₄ is produced for each pulse (intensity) of the laser beam 200 so the yield of SiF₄ per pulse (intensity) is linear up to SF₆ pressure of about 1.5 Torr.

The dissociation of SF₆ decreases exponentially (and then saturates) with increasing SF₆ pressure greater than 1.5 Torr due to collisional deactivation of the excited SF₆ molecules. In an embodiment of the present invention, SF₆ molecules have a mean free path for molecular collision that decreases as gas pressure increases, such as <100 um at 2 Torr, <10 um at 20 Torr, and <2 um at 100 Torr.

In an embodiment of the present invention, atomic F reacts with Silicon in the substrate 300 even at room temperature. In an embodiment of the present invention, atomic F has a mean free path for molecular collision of about 3,000 um at 2 Torr.

In an embodiment of the present invention, gaseous H₂ can be added to scavenge atomic F and produce HF does not etch Silicon (but will etch SiO₂ to produce SiF₄ and water). As a result, the gaseous H₂ prevents diffusion of F to Silicon in the substrate 300 and almost completely suppresses the heterogeneous processes that produce SiF₄.

In an embodiment of the present invention, H₂O (water) is adsorbed on the substrate 300 (and the walls of the process chamber 1010) to scavenge the atomic F and produce HF, which etches SiO₂, but does not etch Silicon. The SF₄ is very reactive and is hydrolyzed by the H₂O (water) to produce SO₂ and HF.

In an embodiment of the present invention, a capacitive manometer adjusts a global pressure in the process chamber 1010 to 7-40 Torr during operation. In an embodiment of the present invention, a capacitive manometer adjusts a global pressure in the process chamber 1010 to 40-200 Torr during operation. In an embodiment of the present invention, a capacitive manometer adjusts the global pressure in the process chamber 1010 to 200-750 Torr during operation.

In an embodiment of the present invention, the process chamber 1010 is pressurized. In an embodiment of the present invention, a capacitive manometer adjusts a global pressure in the process chamber 1010 to 750-1,000 Torr during operation.

During operation, a local pressure in a vicinity, such as within 10-20 um, of a location that the laser beam 200 impinges on the etch chemical 452 and the mounted substrate 300 and frame is different from the global pressure in the process chamber 1010. In an embodiment of the present invention, the local pressure in the vicinity, such as within 10-20 um, of the location that the laser beam 200 impinges on the etch chemical 452 and the mounted substrate 300 and frame is higher than the global pressure in the process chamber 1010. In an embodiment of the present invention, the local pressure in the process chamber 1010 is 30-250 Torr higher than the global pressure during operation.

In an embodiment of the present invention, a global temperature in the process chamber 1010 is 25 (ambient) to 75 degrees Centigrade.

In an embodiment of the present invention, the process chamber 1010 is heated or cooled during operation by circulating a coolant through a heat exchanger 433 and inside the walls (not shown) of the process chamber 1010 to control a temperature of the process chamber 1010. In an embodiment of the present invention, the process chamber 1010 includes walls covered with carbon.

In an embodiment of the present invention, the chuck 432 is heated or cooled during operation by circulating a coolant through the heat exchanger 433 and inside the chuck 432 to control a temperature of the chuck 432. In an embodiment of the present invention, the coolant includes water with additives.

In an embodiment of the present invention, the inert gas diluent is preheated so as to locally heat the substrate 300 and thus modify the etch process. In an embodiment of the present invention, the inert gas diluent is precooled so as to locally cool the substrate 300 and thus modify the etch process.

The band gap, E_{g}, of Silicon is 1.1 eV at a temperature of 300 K. The band gap of Silicon decreases as the temperature increases. For photon energies larger than the band-gap energy, the excitation mechanism at the surface of the Silicon is dominated by generation of electron-hole pairs.

Depending on optical absorption coefficient and thermal conductivity of the wafer 300, a local temperature of the wafer 300 in a vicinity of a location that the laser beam 200 impinges on the wafer 300 during operation may be different from the global temperature in the process chamber 1010.

When in a solid phase, silicon is a semiconductor and absorption of incident electromagnetic radiation, such as light, depends strongly on wavelength. In an embodiment of the present invention, absorption of energy from the light by silicon exceeds 50% for wavelengths of about 400-1,400 nm, with a peak absorption of energy from the light of about 68% (and a penetration depth by the light of about 100 um) at a wavelength of about 1,000 nm. However, when in a liquid (molten) phase, silicon behaves like a metal and absorption of incident electromagnetic radiation, such as light, depends only very slightly on wavelength.

Silicon has a melting point of 1,685 K and a boiling point of 3,173 K. Thermal conductivity of silicon increases significantly after it melts. In an embodiment of the present invention, thermal conductivity of silicon is 150 W/(m-K) in the solid phase and 450 W/(m-K) in the liquid phase.

In an embodiment of the present invention, the laser beam 200 has a fluence of 3.0-9.0 J/cm². Consequently, the local temperature of the outer surface of the wafer 300, such as in a heat-affected zone (HAZ) of within 10-20 um of the location that the laser beam 200 impinges on the wafer 300, is higher than the global temperature in the process chamber 1010.

In an embodiment of the present invention, the laser-assisted chemical etch of silicon in the wafer 300 occurs at a local temperature of 75-200 degrees Centigrade. In an embodiment of the present invention, the laser-assisted chemical etch of silicon in the wafer 300 occurs at a local temperature of 200-400 degrees Centigrade. In an embodiment of the present invention, the laser-assisted chemical etch of silicon in the wafer 300 occurs at a local temperature of 400-600 degrees Centigrade.

If the local temperature of the wafer 300 in the vicinity of the laser beam 200 is high enough, non-volatile byproducts on (or near) the wafer 300 are removed by laser ablation or evaporation.

In an embodiment of the present invention, the non-volatile byproducts include Copper halides, such as CuBr₂, CuCl₂, or CuF₂, or Copper Oxides, such as CuO, depending on the type of etch chemical 452 that is dispensed in the process chamber 1010.

In an embodiment of the present invention, a gas exhaust line 459 with a valve, filter, and a rotary pump transports an excess of the etch chemical 452 out of the process chamber 1010.

In an embodiment of the present invention, the volatile byproducts include Silicon halides, such as SiBr₄, SiCl₄, or SiF₄, depending on the type of etch chemical 452 that is dispensed in the process chamber 1010.

In an embodiment of the present invention, a gas exhaust line 459 with a valve, filter, and a rotary pump transports the volatile byproducts out of the process chamber 1010.

In an embodiment of the present invention, a showerhead dispenses a purge gas 458 towards the mounted substrate 300 and frame held by the chuck 432 in the process chamber 1010 to quench the reaction. In an embodiment of the present invention, the purge gas is an inert gas, such as Argon. In an embodiment of the present invention, the purge gas and the diluent gas include the same type of gas, such as Helium.

In an embodiment of the present invention, the laser-assisted chemical (volumetric) removal rate for silicon in the wafer 300 is 1.2×10⁵ um³/sec. In regime 1, the laser-assisted chemical (volumetric) removal rate scales strongly with laser beam 200 power. In regime 3, the laser-assisted chemical (volumetric) removal rate scales weakly with etch chemical 452 gas pressure.

In an embodiment of the present invention, the laser-assisted chemical (vertical) etch rate for silicon is 2-15 nm/sec in the scribeline or street. In an embodiment of the present invention, the laser-assisted chemical etch rate for silicon is 15-75 nm/sec in the scribeline or street. In an embodiment of the present invention, the laser-assisted chemical etch rate for silicon is 75-225 nm/sec in the scribeline or street.

In an embodiment of the present invention, the laser-assisted chemical (vertical) etch rate for silicon is 0.01-0.15 nm/pulse in the scribeline or street. In an embodiment of the present invention, the laser-assisted chemical etch rate for silicon is 0.15-1.50 nm/pulse in the scribeline or street. In an embodiment of the present invention, the laser-assisted chemical etch rate for silicon is 1.50-7.50 nm/pulse in the scribeline or street.

In an embodiment of the present invention, the robots in the substrate transport mechanism 430 are articulated to provide random access to various processing chambers 1010, 1020.

In an embodiment of the present invention, the singulation apparatus 10 includes multiple process chambers 1010, 1020 arranged in a horizontal plane. In an embodiment of the present invention, the multiple process chambers 1010, 1020 are arranged from left to right. In an embodiment of the present invention, the multiple process chambers 1010, 1020 are arranged from front to back. In an embodiment of the present invention, the multiple process chambers 1010, 1020 are arranged radially in a horizontal plane.

In an embodiment of the present invention, the singulation apparatus 10 includes multiple process chambers 1010, 1020 arranged in a vertical plane. In an embodiment of the present invention, the multiple process chambers 1010, 1020 are stacked vertically in one or more towers. In an embodiment of the present invention, the multiple process chambers 1010, 1020 are arranged radially in a vertical plane.

In an embodiment of the present invention, the multiple mounted substrates 300 and tape frames are processed at different times in the same process chamber 1010. In an embodiment of the present invention, the multiple mounted substrates 300 and tape frames are processed at the same time in different process chambers 1010, 1020.

In an embodiment of the present invention, the multiple process chambers 1010, 1020 run the same process in parallel to increase feed rates or throughput for a product.

In an embodiment of the present invention, the multiple process chambers 1010, 1020 offer a choice of different processes in parallel for different products.

In an embodiment of the present invention, the multiple process chambers 1010, 1020 run different processes in series, such as in sequential processing of a product.

In an embodiment of the present invention, the laser-assisted chemical etch includes two or more types of etches that are performed sequentially. In an embodiment of the present invention, the two or more sequential etches are performed in situ in one process chamber 1010. In an embodiment of the present invention, the two or more sequential etches are performed in separate process chambers 1010, 1020.

In an embodiment of the present invention, the different processes include (a) a laser scribe process, such as with small energy pulses at a high repetition rate, to remove surface layers, such as metal and oxide, of the substrate 300 with a thickness of about 10 um, followed by (b) a laser dice process, such as with large energy pulses, to etch underlying layers, such as bulk silicon in the substrate 300.

In an embodiment of the present invention, the different processes include (a) a first process to etch a cut or trench through the substrate 300, and (b) a second process to modify a slope, such as an undercut, of the sidewalls of the cut or trench.

In an embodiment of the present invention, the laser beam 200 makes one pass to produce the cut when the laser beam 200 has a top hat cross sectional profile. In an embodiment of the present invention, the laser beam 200 is operated at a constant velocity and does not pause until the direction needs to be changed, such as at the end of a row. In an embodiment of the present invention, the laser beam 200 is operated as a collinear series of interrupted strokes in which a pause occurs after each stroke. In an embodiment of the present invention, the stroke may be selected to be equivalent to a length of a side of a die, such as 20-30 mm.

In an embodiment of the present invention, the laser beam 200 has a Gaussian cross sectional profile with a higher intensity near its center. Then, multiple passes are made to smooth out the non-uniformity in the profile of the laser beam 200. The multiple scan lines are separated by a step size that is small enough to result in a large overlap, such as 65-85%.

In an embodiment of the present invention, the laser beam 200 makes 2-12 passes to produce the cut. In an embodiment of the present invention, the laser beam 200 makes 12-50 passes to produce the cut. In an embodiment of the present invention, the laser beam 300 makes 50-100 passes to produce the cut.

In an embodiment of the present invention, the dicing speed is 50-200 mm/sec. In an embodiment of the present invention, the dicing speed is 200-600 mm/sec. In an embodiment of the present invention, the dicing speed is 600-1,200 mm/sec.

In an embodiment of the present invention, the laser-assisted chemical cut includes a sidewall slope which has two regions. An upper ¾ of the sidewall slope is steep and vertical while a lower ¼ of the sidewall slope is shallow with rounded lower corners near a flat bottom.

In an embodiment of the present invention, the laser-assisted chemical cut has a truncated v-shaped profile with sloped sidewalls, sharp bottom corners, and a flat bottom surface (trench floor).

In an embodiment of the present invention, the laser-assisted chemical cut has a u-shaped profile with vertical sidewalls, rounded bottom corners, and a flat bottom surface (trench floor).

In an embodiment of the present invention, the laser-assisted chemical cut has a re-entrant (undercut) profile with an upper lip or overhang, curved sidewalls, rounded bottom corners, and a flat bottom surface (trench floor).

In an embodiment of the present invention, the different processes include (a) a first process to etch through the substrate 300, and (b) a second process to smooth the surface of the sidewalls of the cut or trench.

In an embodiment of the present invention, the different processes include (a) a first process to etch through the substrate 300, and (b) a second process to reduce stress in the substrate 300 near the cut or trench due to the etch.

Otherwise, accumulated stress may relax and cause damage to the substrate 300. In an embodiment of the present invention the damage is manifested macroscopically as micro-cracking in the substrate 300 or delamination of layers of the substrate 300. In an embodiment of the present invention the damage is manifested microscopically as dislocations within the crystalline lattice of the substrate 300.

In an embodiment of the present invention, the stress is reduced by annealing the substrate 300 in a localized region around the cut or trench, such as with a flash anneal or spike anneal. In an embodiment of the present invention, the stress is reduced by heating the substrate 300 along the edges and sidewalls of the cut or trench, such as with a laser. In an embodiment of the present invention, the stress is reduced by removing the damaged area, such as with a wet etch or dry etch.

In an embodiment of the present invention, the different processes include (a) a first process to etch through the substrate, and (b) a second process to remove contamination, such as redeposited material, or recast, from the laser.

In an embodiment of the present invention, the substrate 300 is cleaned by bombarding with ions, such as Argon.

In an embodiment of the present invention, the substrate 300 is cleaned with a plasma.

In an embodiment of the present invention, a fast deep etch to make a rough cut in a central trench is followed by slow etches along both sides of the central trench to smooth the surface of the sidewalls of the cut or trench.

In an embodiment of the present invention, a shallow etch in two parallel narrow trenches along both edges of the scribeline, such as to prevent lateral defect propagation as a crack-stop or to limit lateral heat spreading by conduction, is followed by a deep central etch to connect the two parallel narrow trenches.

In an embodiment of the present invention, a wide shallow central etch is followed by a narrow deep central etch.

In an embodiment of the present invention, a narrow deep central etch is followed by a wide shallow central etch.

In an embodiment of the present invention, if a die shift or a die rotation is present in the die in a row, every die in the row is aligned separately and cut through a center of the street in that row.

In an embodiment of the present invention, the laser-assisted chemical etch is performed in two orthogonal orientations. A wafer is first cut into rows in process chamber 1010. Then, the rows are cut into chips in a separate process chamber 1020.

In an embodiment of the present invention, etching in one orientation only in each process chamber allows a faster feedfrate.

In an embodiment of the present invention, alternating between etching in a forward direction and etching in a reverse direction in adjacent rows also allows a faster feedrate. In an embodiment of the present invention, bi-directional laser assisted chemical etch is used to cut rows only.

In an embodiment of the present invention, the trench floor of the laser-assisted chemical cut has a roughness of 15.2 nm root mean square (RMS). In an embodiment of the present invention, the trench floor has a roughness of 20 nm RMS.

In an embodiment of the present invention, a depth of the laser-assisted chemical cut is 45-60 um. In an embodiment of the present invention, a depth of the laser-assisted chemical cut is 30-45 um. In an embodiment of the present invention, a depth of the laser-assisted chemical cut is 15-30 um. In an embodiment of the present invention, a depth of the laser-assisted chemical cut is 6-15 um.

In an embodiment of the present invention, a width of the laser-assisted chemical cut is 90-120 um. In an embodiment of the present invention, a width of the laser-assisted chemical cut is 60-90 um. In an embodiment of the present invention, a width of the laser-assisted chemical cut is 40-60 um. In an embodiment of the present invention, a width of the laser-assisted chemical cut is 20-40 um. The cut is positioned in the scribelines or street that separate adjacent die on the wafer 300.

In an embodiment of the present invention, an aspect ratio of depth to width of the laser-assisted chemical cut is (0.07-0.25):1.00. In an embodiment of the present invention, an aspect ratio of depth to width of the laser-assisted chemical cut is (0.25-0.75):1.00. In an embodiment of the present invention, an aspect ratio of depth to width of the laser-assisted chemical cut is (0.75-2.50):1.00. In an embodiment of the present invention, an aspect ratio of depth to width of the laser-assisted chemical cut is (3.00-5.00):1.00.

In an embodiment of the present invention, a sidewall slope of the laser-assisted chemical cut is 60-70 degrees. In an embodiment of the present invention, a sidewall slope of the laser-assisted chemical cut is 70-80 degrees. In an embodiment of the present invention, a sidewall slope of the laser-assisted chemical cut is 80-90 degrees. In an embodiment of the present invention, a sidewall slope of the laser-assisted chemical cut is 90-100 degrees (re-entrant profile).

Invasiveness refers to thermally-induced or chemically-induced changes in a region of the wafer 300 near the laser-assisted chemical cut. The invasiveness may be physically observable and/or electrically detectable. Invasiveness cannot be avoided, but should be limited to a small horizontal and vertical proximity from the laser-assisted chemical cut. An invasiveness-free zone does not include any defect, damage, or non-homogeneity associated with the laser-assisted chemical etch.

In an embodiment of the present invention, invasiveness to an underlying device is limited to a vertical proximity of 5-10 um. In an embodiment of the present invention, invasiveness to an underlying device is limited to a vertical proximity of 10-15 um. In an embodiment of the present invention, invasiveness to an underlying device is limited to a vertical proximity of 15-20 um.

In an embodiment of the present invention, the laser-assisted chemical etch produces a cut that is straighter (laterally), steeper (vertically), smoother, has less damage, or has less induced stress. In an embodiment of the present invention, the laser-assisted chemical etch produces a cut with less die chipping, micro-cracking, or delamination of interlevel dielectric (ILD) passivation, especially for low dielectric constant (k) or ultra-low k material. In an embodiment of the present invention, the laser-assisted chemical etch produces a cut with greater die edge fracture strength.

After singulation, the substrate 300 may go through other processes, such as cleaning, inspection, storage, die separation, and pick-and-place. Die inspection includes 100% visual inspection at 100× magnification with a microscope. Olympus makes inspection equipment. Viking makes die separation equipment. Apollo and Viking make pick-and-place equipment.

Many embodiments and numerous details have been set forth above in order to provide a thorough understanding of the present invention. One skilled in the art will appreciate that many of the features in one embodiment are equally applicable to other embodiments. One skilled in the art will also appreciate the ability to make various equivalent substitutions for those specific materials, processes, dimensions, concentrations, etc. described herein. It is to be understood that the detailed description of the present invention should be taken as illustrative and not limiting, wherein the scope of the present invention should be determined by the claims that follow.

We claim:

1. An apparatus comprising:
a stage;
multiple chucks mounted on said stage;
multiple process chambers disposed adjacent to said stage;
a substrate transport mechanism to transfer multiple substrates to said multiple chucks, wherein each of said multiple chucks holds one of said multiple substrates in one of said multiple process chambers;
a gas feed line to dispense an etch chemical towards each of said multiple substrates;
a laser beam directed at each of said multiple substrates; and
a gas exhaust line to remove any excess of said etch chemical and said volatile byproducts.

2. The apparatus of claim 1 further comprising a focusing mechanism for said laser beam.

3. The apparatus of claim 1 further comprising a steering mechanism for said laser beam.

4. The apparatus of claim 1 further comprising an optical scanning mechanism for said laser beam.

5. The apparatus of claim 1 further comprising a mechanical scanning system for said chuck.

6. The apparatus of claim 1 wherein said laser beam comprises ultraviolet light.

7. The apparatus of claim 1 wherein said laser beam comprises an excimer laser.

8. The apparatus of claim 1 wherein said laser beam comprises a shape of an ellipse in cross-section.

9. The apparatus of claim 1 wherein said laser beam has a variable spot size.

10. The apparatus of claim 3 wherein said steering mechanism comprises galvanometer (galvo) mirrors.

11. The apparatus of claim 1 wherein said chucks comprise electrostatic chucks.

12. The apparatus of claim 1 wherein a coolant is circulated inside said chucks to control temperature.

13. A method comprising:
directing a laser beam at a wafer held by a chuck in a process chamber;
inducing an etch chemical with said laser beam to undergo photolytic dissociation to radicals;
reacting said radicals with said wafer to form volatile byproducts;
removing said volatile byproducts; and
singulating said wafer.

14. The method of claim 13 further comprising optically scanning said laser beam.

15. The method of claim 13 further comprising mechanically scanning said wafer.

16. The method of claim 13 further comprising optically scanning said laser beam and mechanically scanning said wafer.

17. A method comprising:
directing a laser beam at a wafer held by a chuck in a process chamber;
heating said wafer to a high temperature;
inducing an etch chemical with said high temperature to undergo pyrolytic dissociation to radicals;
reacting said dissociated etch chemical with said wafer to form volatile byproducts;
removing said volatile byproducts; and
singulating said wafer.

18. The method of claim 17 further comprising optically scanning said laser beam.

19. The method of claim 17 further comprising mechanically scanning said wafer.

20. The method of claim 17 further comprising optically scanning said laser beam and mechanically scanning said wafer.

21. The method of claim 17 further comprising: inducing said etch chemical with said laser beam to undergo photolytic dissociation to form radicals.
